(19) United States
(12) Patent Application Publication
(10) Pub. No.: US 2026/0231704 A1
(43) Pub. Date: Aug. 6, 2026

(54) METHOD FOR FORMING SEMICONDUCTOR STRUCTURE

(71) Applicant: NANYA TECHNOLOGY CORPORATION, New Taipei City (TW)

(72) Inventor: Yi Long Wong, New Taipei City (TW)

(73) Assignee: NANYA TECHNOLOGY CORPORATION, New Taipei City (TW)

(21) Appl. No.: 19/047,500

(22) Filed: Feb. 6, 2025

(51) Int. Cl. H01L 21/266; H01L 21/265

(52) U.S. Cl. CPC H10P 30/22; H10P 30/222

(57) ABSTRACT

A method for forming a semiconductor structure is provided, which includes following steps. A stacked structure including a floating gate layer, an inter-gate dielectric layer, and a control gate layer stacked on the tunneling oxide material layer in sequence is formed on a tunneling oxide material layer on a substrate. A first spacer material layer is formed on the tunneling oxide material layer to cover a top surface and sidewalls of the stacked structure. A second spacer material layer is formed on the first spacer material layer. A mask pattern is formed on the second spacer material layer and side portions of the second spacer material layer are exposed by the mask pattern. An ion implant process is performed on side portions of the first spacer material layer through the side portions of the second spacer material layer to form first doped regions in the first spacer material layer.

### BACKGROUND

### Technical Field

The present invention relates to a method for forming a semiconductor structure, more particularly, to a method for forming a memory structure.

### Description of Related Art

A flash memory device is a type of a non-volatile memory that allows multiple data writing, reading, and erasing operations, and the stored data will be retained even after power to the device is removed. With these advantages, the flash memory has been broadly applied in an electronic component. Typically, the flash memory device may have a floating gate and a control gate on the floating gate in which the floating gate is isolated from the control gate by an inter-gate dielectric layer interposed therebetween, and the floating gate is isolated from the substrate by a tunnel oxide layer interposed therebetween.

As integrated circuits (ICs) are aiming toward a higher level of integration through miniaturization, the dimension of each memory cell in the flash memory device must be reduced in order to increase the integration of memory devices. However, as the sizes of the electronic components continue to decrease, there is a continuous need to address problems coming from a shrinking process. For example, the channel length under the tunnel oxide layer and the distance between the lightly doped regions (LDDs) may become more significant to the electrical properties of the device memory.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

The disclosure provides a method for forming a semiconductor structure in which an ion implant process is performed on side portions of a first spacer material layer through side portions of a second spacer material layer on the first spacer material layer, so that first doped regions are formed in the first spacer material layer adjacent to surfaces of the side portions of the first spacer material layer. As such, the film quality of the first spacer material layer where the first doped regions are formed therein can be improved, and thus the first spacer layer formed through the subsequent processes can have a desired profile on the opposite sidewalls of the stacked structure.

An embodiment of the present disclosure provides a method for forming a semiconductor structure, which includes following steps. A tunneling oxide material layer is formed on a substrate. A stacked structure is formed on the tunneling oxide material layer, wherein the stacked structure includes a floating gate layer, an inter-gate dielectric layer, and a control gate layer stacked on the tunneling oxide material layer in sequence. A first spacer material layer is formed on the tunneling oxide material layer to cover a top surface and opposite sidewalls of the stacked structure. A second spacer material layer is formed on the first spacer material layer. A mask pattern is formed on the second spacer material layer, wherein side portions of the second spacer material layer on the opposite sidewalls of the stacked structure are exposed by the mask pattern. An ion implant process is performed on side portions of the first spacer material layer through the side portions of the second spacer material layer to form first doped regions in the first spacer material layer adjacent to surfaces of the side portions of the first spacer material layer.

In some embodiments, the ion implant process is performed in which an implant energy is about 1 keV, an implant dosage is ranging from 3×10⁵ to 3×10⁶, and an implant angle is ranging from 10° to 35°.

In some embodiments, the first spacer material layer is a nitride layer, the second spacer material layer is an oxide layer, and an element doping in the doped region includes nitrogen.

In some embodiments, an atomic concentration of nitrogen in the first doped regions of the first spacer material layer is greater than an atomic concentration of nitrogen in other regions of the first spacer material layer.

In some embodiments, second doped regions are formed in the side portions of the second spacer material layer during the ion implant process.

In some embodiments, a thickness of the first spacer material layer is ranging from 60 Å to 70 Å.

In some embodiments, a thickness of the second spacer material layer is ranging from 45 Å to 55 Å.

In some embodiments, wherein the mask pattern includes a first portion covering top portion of the second spacer material layer over the top surface of the stacked structure and a second portion covering a bottom portion of the second spacer material layer over the substrate at opposite sidewalls of the stacked structure.

In some embodiments, the method further includes following steps. The mask pattern is removed after the first doped regions are formed. The second spacer material layer is removed after the mask pattern is removed. Portions of the first spacer material layer and portions of the tunneling oxide material layer are removed to form a first spacer layer including the first doped regions and covering the top surface and the opposite sidewalls of the stacked structure, and a tunneling oxide layer between the substrate and the stacked structure.

In some embodiments, the method further includes a step of forming lightly doped regions in the substrate at the opposite sidewalls of the stacked structure by using the first spacer layer as a mask layer.

Based on the above, in the aforementioned method for forming the semiconductor structure, the ion implant process is designed to perform on the side portions of the first spacer material layer through the side portions of the second spacer material layer, so that first doped regions are formed in the first spacer material layer adjacent to surfaces of the side portions of the first spacer material layer. As such, the film quality of the first spacer material layer where the first doped regions are formed therein can be improved, and thus the first spacer layer can be formed, through the subsequent processes, to have a desired profile on the opposite sidewalls of the stacked structure. Accordingly, the electrical properties of the memory device including the semiconductor structure can be improved since the distance between the lightly doped regions formed in the substrate is stable.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1F are schematic cross-sectional views of a method for forming a semiconductor device according to an embodiment of the disclosure.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements. As used herein, “electrical connection” may refer to the concept including a physical connection (e.g., wired connection) and a physical disconnection (e.g., wireless connection).

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

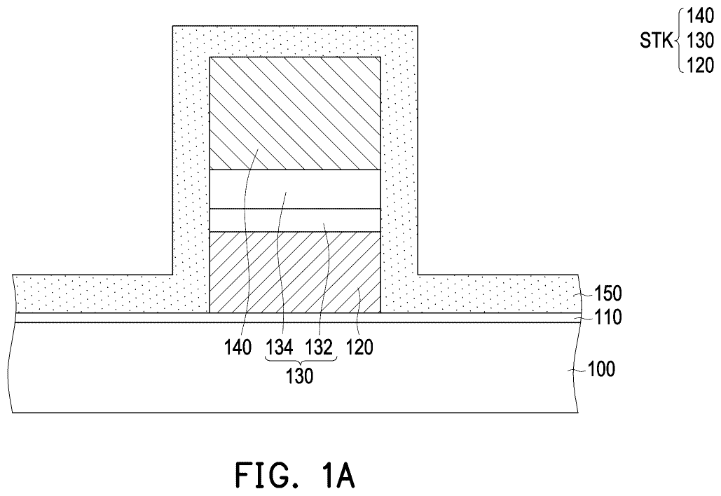

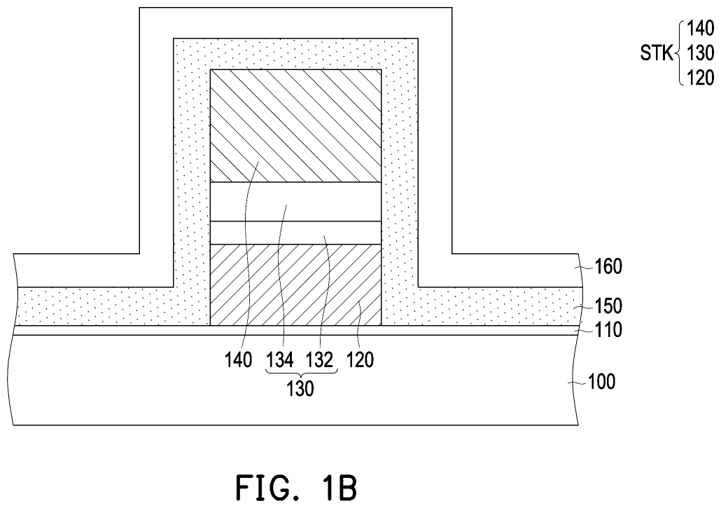

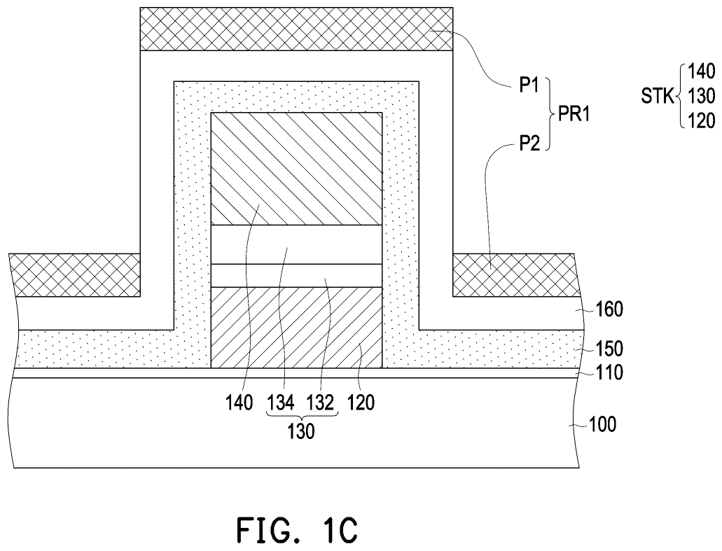

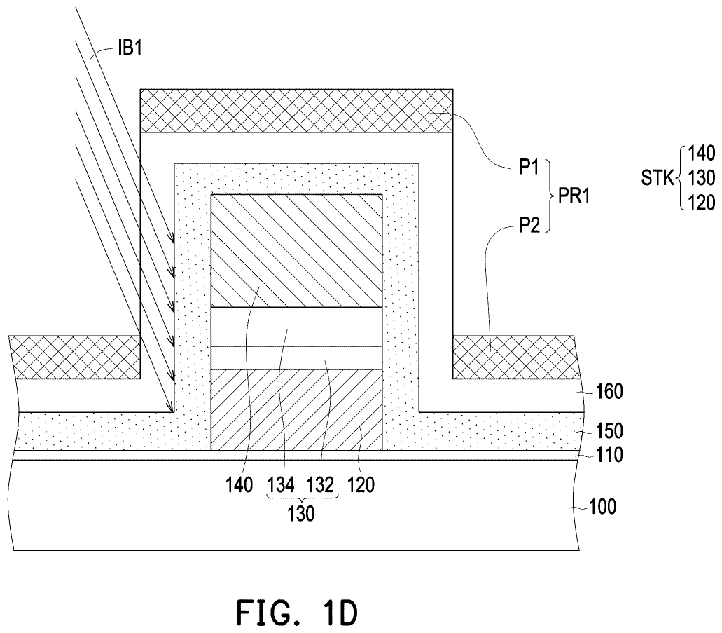

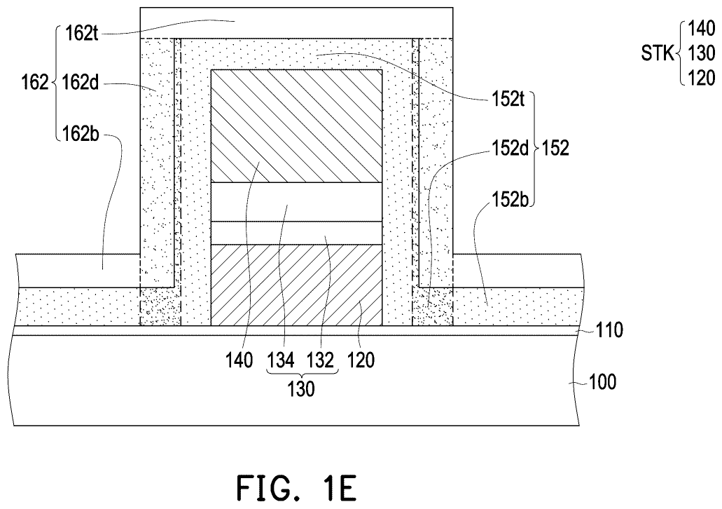

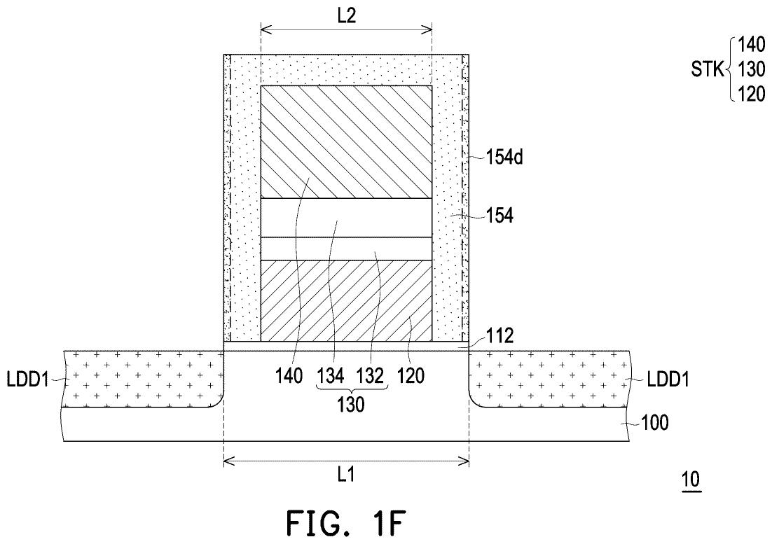

FIG. 1A to FIG. 1F are schematic cross-sectional views of a method for forming a semiconductor device according to an embodiment of the disclosure.

In this embodiment, a method for forming a semiconductor structure (e.g., a semiconductor structure 10 shown in FIG. 1F) includes following steps.

Firstly, referring to FIG. 1A, a tunneling oxide material layer 110 is formed on a substrate 100. In some embodiments, the substrate 100 may include a semiconductor substrate or a semiconductor-on-insulator (SOI) substrate. The semiconductor materials in the semiconductor substrate or in the SOI substrate may include an element semiconductor, an alloy semiconductor, or a compound semiconductor. For example, the element semiconductor may include Si or Ge. The alloy semiconductor may include SiGe, SiGeC, or the like. The compound semiconductor may include SiC, III-V semiconductor materials, or II-VI semiconductor materials. The III-V semiconductor materials may include GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, or InAlPAs. The II-VI semiconductor materials may include CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe. The semiconductor material may be doped with a dopant of a first conductivity type or a dopant of a second conductivity type complementary to the first conductivity type. For example, the first conductivity type may be n-type, whereas the second conductivity type may be p-type. The tunneling oxide material layer 110 may include a material suitable for the tunneling oxide layer such as oxide (e.g., silicon oxide).

Next, a stacked structure STK is formed on the tunneling oxide material layer 110. The stacked structure STK includes a floating gate layer 120, an inter-gate dielectric layer 130, and a control gate layer 140 stacked on the tunneling oxide material layer 110 in sequence. The floating gate layer 120 may include a material suitable for the floating gate such as polysilicon. The inter-gate dielectric layer 130 may include a first layer 132 on the floating gate layer 120 and a second layer 134 on the first layer 132. The first layer 132 and the second layer 134 may each include a material suitable for the inter-gate dielectric layer such as oxide (e.g., silicon oxide), nitride (e.g., silicon nitride), or a combination thereof. In some embodiments, the material of the first layer 132 may be different from the material of the second layer 134. The control gate layer 140 may include a material suitable for the control gate such as polysilicon.

Then, a first spacer material layer 150 is formed on the tunneling oxide material layer 110 to cover a top surface and opposite sidewalls of the stacked structure STK. The first spacer material layer 150 may include a material suitable for the spacer such as nitride (e.g., silicon nitride). In this embodiment, the first spacer material layer 150 may be conformally formed on a top surface of the tunneling oxide material layer 110 and the top surface and the opposite sidewalls of the stacked structure STK. In some embodiment, a thickness of the first spacer material layer 150 is ranging from 60 Å to 70 Å.

After that, referring to FIG. 1B, a second spacer material layer 160 is formed on the first spacer material layer 150. In this embodiment, the second spacer material layer 160 may be formed of a material different from the material of the first spacer material layer 150. For example, in the case where the first spacer material layer 150 is made by nitride (e.g., silicon nitride), the second spacer material layer 160 may be made by oxide (e.g., silicon oxide). In other words, the first spacer material layer 150 may be a nitride layer, and the second spacer material layer 160 may be an oxide layer. In this embodiment, the second spacer material layer 160 may be conformally formed on a surface of the first spacer material layer 150. In some embodiment, a thickness of the second spacer material layer 160 is ranging from 60 Å to 70 Å.

Next, referring to FIG. 1C, a mask pattern PR1 is formed on the second spacer material layer 160, wherein side portions of the second spacer material layer 160 over the opposite sidewalls of the stacked structure STK are exposed by the mask pattern PR1. In this embodiment, the mask pattern PR1 may include a first portion P1 covering a top portion of the second spacer material layer 160 over the top surface of the stacked structure STK and a second portion P2 covering a bottom portion of the second spacer material layer 160 over the substrate 100 at the opposite sidewalls of the stacked structure STK. In some embodiments, the mask pattern PR1 may be a photoresist pattern, but is not limited thereto. In some alternative embodiments, the mask pattern PR1 may be made of a material being capable of blocking the ion beams subjecting to the layers covered by the mask pattern PR1.

Then, referring to FIG. 1D and FIG. 1E, an ion implant process is performed on side portions of the first spacer material layer 150 on the opposite sidewalls of the stacked structure STK through the side portions of the second spacer material layer 160, so as to form first doped regions 152d in the first spacer material layer 152 adjacent to surfaces of the side portions of the first spacer material layer 152. In this embodiment, the ion implant process is performed in which an implant energy is about 1 keV, an implant dosage is ranging from 3×10⁵ to 3×10⁶, and an implant angle is ranging from 10° to 35°. That is, the ion beams IB1 are tilted at an angle ranging from 10° to 35° with respect to the normal line of the top surface of the substrate 100. In some embodiments, the implant angle is about 23°. In the case where the first spacer material layer 150 is a nitride layer and the second spacer material layer 160 is an oxide layer, an element doping in the doped region 152d of the first spacer material layer 152 includes nitrogen. In this embodiment, an atomic concentration of nitrogen in the first doped regions 152d of the first spacer material layer 152 is greater than an atomic concentration of nitrogen in other regions (e.g., a top region 152t and a bottom region 152b) of the first spacer material layer 152.

In some embodiments, the second doped regions 162d are formed in the side portions of the second spacer material layer 162 during the ion implant process. In this embodiment, an atomic concentration of nitrogen in the second doped regions 162d of the second spacer material layer 162 is greater than an atomic concentration of nitrogen in other regions (e.g., a top region 162t and a bottom region 162b) of the second spacer material layer 162. In some embodiments, in the case where the implant angle is relatively low within the range of 10° to 35° (e.g., an angle ranging from 10° to 23°), the doped region 152d of the first spacer material layer 152 may be formed below the second doped regions 162d and between the second doped regions 162d and the tunneling oxide material layer 110.

Then, the mask pattern PR1 is removed after the first doped regions 152d are formed. In some embodiments, the mask pattern PR1 may be removed by, for example, an ashing process or other applicable semiconductor processes.

Then, referring to FIGS. 1E and 1F, after removing the mask pattern PR1, the second spacer material layer 162, portions of the first spacer material layer 152 and portions of the tunneling oxide material layer 110 under the portions of the first spacer material layer 152 are removed to form a first spacer layer 154 including first doped regions 154d and covering the top surface and the opposite sidewalls of the stacked structure STK, and a tunneling oxide layer 112 between the substrate 100 and the stacked structure STK. Due to the film quality of the first spacer material layer 152 where the first doped regions 152d are formed therein is improved, the first spacer layer 154 is formed to have a desired profile (e.g., a vertical profile without any significant undercut contour) on the opposite sidewalls of the stacked structure STK after performing a process of removing the second spacer material layer 162, the portions of the first spacer material layer 152 and the portions of the tunneling oxide material layer 110. For example, when an etching process is applied to the process of removing the second spacer material layer 162, the portions of the first spacer material layer 152 and the portions of the tunneling oxide material layer 110, the first doped regions 152d formed adjacent to the surface of the first spacer material layer 152 may have an improved etch resistance, so that the etch rate of the first doped regions 152d in the first spacer material layer 152 can be decreased during the etching process. As such, the first spacer layer 154 can be prevented from forming an undesirable profile such as undercut. In some embodiments, the desired profile may be, for example, corresponded to the profile of the sidewall of the stacked structure STK.

After that, lightly doped regions LDD1 are formed in the substrate 100 at the opposite sidewalls of the stacked structure STK by using the first spacer layer 154 as a mask layer. In the case where the first spacer layer 154 is formed to have a desired profile (e.g., a vertical profile without any significant undercut contour), the lightly doped regions LDD1 are formed to have a desired distance between the lightly doped regions LDD1. As such, the channel length L2 under the stacked structure STK and the distance L1 between the lightly doped regions LDD1 are formed stably, so that the electrical properties of the memory device including the semiconductor structure 10 can be improved accordingly. If the distance L1 between the lightly doped regions LDD1 are too small with respect to the channel length L2, leakage may be occurred caused by the short channel effect, and the process margin may be insufficient. If the distance L1 between the lightly doped regions LDD1 are too large with respect to the channel length L2, the electrical properties of the memory device including the semiconductor structure 10 may be decreased. As such, it is important to have the lightly doped regions LDD1 with a desire and stable distance L1 between the lightly doped regions LDD1. In some embodiments, halo regions (not illustrated) may be formed under the lightly doped regions LDD1, but is not limited thereto.

In summary, in the aforementioned method for forming the semiconductor structure the ion implant process is designed to perform on the side portions of the first spacer material layer through the side portions of the second spacer material layer, so that first doped regions are formed in the first spacer material layer adjacent to the surfaces of the side portions of the first spacer material layer. As such, the film quality of the first spacer material layer where the first doped regions are formed therein can be improved, and thus the first spacer layer can be formed, through the subsequent processes, to have a desired profile on the opposite sidewalls of the stacked structure. Accordingly, the electrical properties of the memory device including the semiconductor structure can be improved since the distance between the lightly doped regions formed in the substrate is stable.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method for forming a semiconductor structure, comprising:
forming a tunneling oxide material layer on a substrate;
forming a stacked structure on the tunneling oxide material layer, wherein the stacked structure comprises a floating gate layer, an inter-gate dielectric layer, and a control gate layer stacked on the tunneling oxide material layer in sequence;
forming a first spacer material layer on the tunneling oxide material layer to cover a top surface and opposite sidewalls of the stacked structure;
forming a second spacer material layer on the first spacer material layer;
forming a mask pattern on the second spacer material layer, wherein side portions of the second spacer material layer on the opposite sidewalls of the stacked structure are exposed by the mask pattern; and
performing an ion implant process on side portions of the first spacer material layer through the side portions of the second spacer material layer to form first doped regions in the first spacer material layer adjacent to surfaces of the side portions of the first spacer material layer.

2. The method of claim 1, wherein the ion implant process is performed in which an implant energy is about 1 keV, an implant dosage is ranging from 3×10⁵ to 3×10⁶, and an implant angle is ranging from 10° to 35°.

3. The method of claim 2, wherein the first spacer material layer is a nitride layer, the second spacer material layer is an oxide layer, and an element doping in the doped region comprises nitrogen.

4. The method of claim 3, wherein an atomic concentration of nitrogen in the first doped regions of the first spacer material layer is greater than an atomic concentration of nitrogen in other regions of the first spacer material layer.

5. The method of claim 1, wherein second doped regions are formed in the side portions of the second spacer material layer during the ion implant process.

6. The method of claim 1, wherein a thickness of the first spacer material layer is ranging from 60 Å to 70 Å.

7. The method of claim 1, wherein a thickness of the second spacer material layer is ranging from 45 Å to 55 Å.

8. The method of claim 1, wherein the mask pattern comprises a first portion covering a top portion of the second spacer material layer over the top surface of the stacked structure and a second portion covering a bottom portion of the second spacer material layer over the substrate at the opposite sidewalls of the stacked structure.

9. The method of claim 1, further comprising:
removing the mask pattern after forming the first doped regions;
removing the second spacer material layer after removing the mask pattern; and
removing portions of the first spacer material layer and portions of the tunneling oxide material layer to form a first spacer layer comprising the first doped regions and covering the top surface and the opposite sidewalls of the stacked structure, and a tunneling oxide layer between the substrate and the stacked structure.

10. The method of claim 9, further comprising:
forming lightly doped regions in the substrate at the opposite sidewalls of the stacked structure by using the first spacer layer as a mask layer.
